(19) United States
(12) Patent Application Publication
(10) Pub. No.: US 2008/0037686 A1
(43) Pub. Date: Feb. 14, 2008

(54) WIRELESS TRANSMISSION METHOD USING OFDM AND TRANSMITTER AND RECEIVER THEREOF

(76) Inventors: Koji AKITA, Yokohama-shi (JP); Noritaka Deguchi, Kawasaki-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 11/838,254

(22) Filed: Aug. 14, 2007

Related U.S. Application Data
(63) Continuation of application No. PCT/JP07/61503, filed on May 31, 2007.

(30) Foreign Application Priority Data
Aug. 14, 2006 (JP) 2006-221028

(51) Int. Cl. H03C 3/00; H04J 1/00; H04Q 7/00

(52) U.S. Cl. 375/302; 370/330; 370/485

(57) ABSTRACT

A wireless transmitter includes an allocation unit allocating first modulation symbols to first subcarriers arranged in N subcarriers cycles, modulators performing OFDM modulation on the first modulation symbols allocated to the first subcarriers to generate OFDM signals including at least one OFDM symbol corresponding to the first modulation symbol, a cyclic delayer performing cyclic delay on the OFDM symbol in the delay amount corresponding to d/N times the symbol length, and transmission units transmitting the OFDM signals.

### CROSS-REFERENCE TO RELATED APPLICATIONS

This is a Continuation Application of PCT Application No. PCT/JP2007/061503, filed May 31, 2007, which was published under PCT Article 21(2) in English.

This application is based upon and claims the benefit of priority from prior Japanese Patent Application No. 2006-221028, filed Aug. 14, 2006, the entire contents of which are incorporated herein by reference.

### BACKGROUND OF THE INVENTION

1. Field of the Invention

The present invention relates to a wireless transmission method using orthogonal frequency division multiplexing (OFDM) and a transmitter and a receiver thereof.

2. Description of the Related Art

In a wireless communication system using OFDM, such as in a mobile communication system, a transmitter carries out modulation on the frequency axis, thereby facilitating the equalization of multipath fading at the receiver. Further, in the case where a plurality of paths exists between the transmitter and the receiver, reception characteristic is improved by a space diversity effect among the paths. A cyclic delay diversity is known as a method to artificially achieve the space diversity effect.

In US 2005/0281240 A1, an OFDM mobile communication system which applies cyclic delay diversity is disclosed in FIG. 2. As is described in US 2005/0281240 A1, in the case of applying cyclic delay diversity to the OFDM mobile communication system, a cyclic delay is performed in a different delay amount among each of the antennas when transmitting the OFDM signals from a plurality of transmitting antennas. In US 2005/0281240 A1, the delay amount of cyclic delay is set so as to preferably maximize the difference among the delay amounts. The signals which have undergone cyclic delay are handled equivalent to delay waves at the receiver end. Consequently, paths are formed in equivalent numbers of the transmitting antennas, and a diversity effect can be obtained thereby.

Cyclic delay is a process performed on the time axis, which is widely known as being mathematically equivalent to a process of performing phase rotation in a constant angular rate proportional to the delay amount on the frequency axis. Accordingly, the process of performing cyclic delay on the OFDM signal is mathematically equivalent to the process of performing the phase rotation on each subcarrier of the OFDM signals on the frequency axis.

In the case of performing cyclic delay diversity in the OFDM communication system in this manner, the phase rotation is performed on the subcarriers. When the phase rotation like this occurs, generally, the relative phase relations among the subcarriers change. This is the same in the case of setting the delaying time of the cyclic delay as in US 2005/0281240 A1. From a practical standpoint, it is not preferable that the relative phase relations among the subcarriers (the phase difference among the subcarriers) vary in the OFDM signals.

For instance, in the case where the signals allocated to the subcarriers are multiplied by codes to bring about orthogonality or pseudo orthogonality among the subcarriers, when the relative phase relations among the subcarriers undergo changes due to the cyclic delay, the orthogonality or pseudo orthogonality is no longer maintained. In addition, when the relative phase relations among the subcarriers change, differential coding, which describes information by the phase difference among subcarriers and transmits such information, can no longer be used.

The object of the present invention is to eliminate or minimize the change in phase difference among subcarriers caused by cyclic delay when applying cyclic delay diversity to the OFDM communication system.

### BRIEF SUMMARY OF THE INVENTION

According to an aspect of the present invention, a wireless transmitter using an orthogonal frequency division multiplexing (OFDM), comprising: an allocation unit configured to allocate a first modulation symbol to a plurality of first subcarriers arranged in N (N is an integer equal to 2 or more) subcarriers cycles; a modulator to perform OFDM modulation on the first modulation symbol to generate an OFDM signal including at least one OFDM symbol corresponding to the first modulation symbol; a cyclic delayer to perform cyclic delay on the OFDM symbol in the delay amount corresponding to either one of d/N times (d is an integer from 0 to N−1) and d/N/M times (M is an integer equal to 2 or more, d is an integer from 0 to M−1) the length of the OFDM symbol; and a transmitting unit configured to transmit the OFDM signal is provided.

### BRIEF DESCRIPTION OF THE SEVERAL VIEWS OF THE DRAWING

FIG. 1 is a block diagram showing an example of a transmitter according to a first embodiment.

FIG. 2 shows an example of an allocation of a first modulation symbol.

FIG. 3 shows an example of the allocation of the first modulation symbol.

FIG. 4 shows an example of the allocation of the first modulation symbol.

FIG. 5 shows an example of the allocation of the first modulation symbol.

FIG. 6 shows an example of the allocation of the first modulation symbol.

FIG. 7 shows an example of the allocation of the first modulation symbol.

FIG. 8 is a block diagram showing another example of the transmitter according the first embodiment.

FIG. 9 shows an example of a receiver according to the first embodiment.

FIG. 10 is a block diagram showing an example of the transmitter according to a second embodiment.

FIG. 11 is a block diagram showing another example of the transmitter according to the second embodiment.

FIG. 12 shows an example of the receiver according to the second embodiment.

FIG. 13 shows an example of a cell sector configuration.

FIG. 14 is a block diagram showing an example of a wireless transmission system according to a third embodiment.

FIG. 15 is a block diagram showing another example of the wireless transmission system according to the third embodiment.

### DETAILED DESCRIPTION OF THE INVENTION

The embodiment of the present invention will be explained below in reference to the drawings.

### First Embodiment

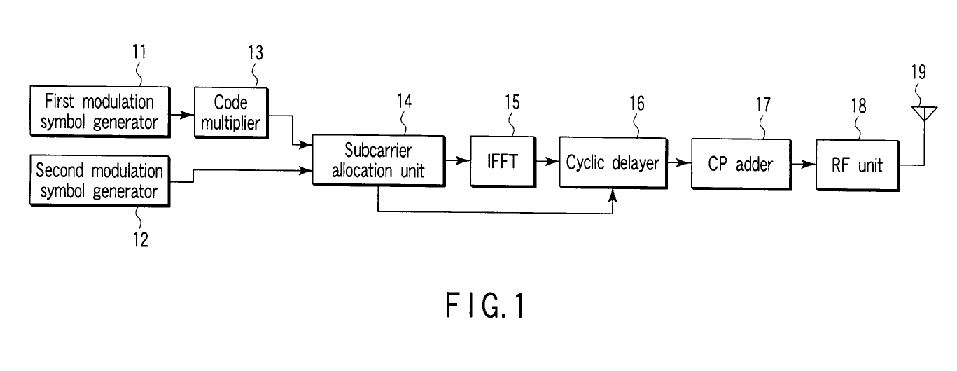

In reference to FIG. 1, a first modulation symbol generator 11 and a second modulation symbol generator 12 respectively generates a first modulation symbol and a second modulation symbol by a digital modulation scheme such as by quadrature phase shift keying (QPSK) or by quadrature amplitude modulation (QAM).

The first modulation symbol generator 11 generates the first modulation symbol by modulating a bit string of a known signal between the transmitter and receiver, such as a pilot signal. As is well known, pilot signals are used for channel estimation (also termed as propagation path estimation). The second modulation symbol generator 12 generates the second modulation symbol by modulating a bit string of, for example, a data signal. The first modulation symbol generator 11 and the second modulation symbol generator 12 need not necessarily possess modulation functions themselves. Therefore, they may also be, for example, a memory in which the first modulation symbol and the second modulation symbol are stored in advance.

In a code multiplier 13, the first modulation symbol is multiplied by a code. The “code” mentioned here is a sequence of complex numbers. The first modulation symbol multiplied by the code is input to a subcarrier allocation unit 14. Meanwhile, the second modulation symbol is input directly to the subcarrier allocation unit 14. The subcarrier allocation unit 14 allocates the first modulation symbol multiplied by the code to a plurality of subcarriers (first subcarriers) arranged at N cycle (N is an integer equal to two or more) of the OFDM symbol, and allocates the second modulation symbol to other plurality of subcarriers (second subcarriers) of the OFDM symbol. The first subcarriers and the second subcarriers are selected from subcarrier groups prepared for the OFDM symbol.

The first modulation symbol allocated to the first subcarriers and the second modulation symbol allocated to the second subcarriers by the subcarrier allocation unit 14 are converted from signals of a frequency domain to signals of a time domain by an inverse fast Fourier transform (IFFT) unit 15, thereby generating an OFDM signal. Here, the OFDM signal includes at least one OFDM symbol corresponding to the first modulation symbol and the second modulation symbol. The subcarrier allocation unit 14 and the IFFT unit 15 form an OFDM modulator which performs OFDM modulation for the first modulation symbol and the second modulation symbol.

The OFDM signal generated by the OFDM modulator in this manner is input to a cyclic delayer 16. In the cyclic delayer 16, a cyclic delay is performed on the input OFDM symbols. Here, the delay amount of cyclic delay in the cyclic delayer 16 is set so as to meet the value corresponding to d/N (d is an integer from 0 to N−1) times the length of the OFDM symbol, in accordance with the information related to subcarrier allocation (especially, the information of cycle N of the first subcarrier to which the first modulation symbol is allocated), which is given from the subcarrier allocation unit 14. The value corresponding to d/N times the length of the OFDM symbol refers to the following values. When the value of d/N times the length of the OFDM symbol is an integral value, it refers to the integral value, and when it is a non-integral value, it refers to an integral value obtained by performing a rounding operation on the non-integral value as will be explained latter.

A cyclic prefix CP adder 17 adds a CP to the OFDM signal output from the cyclic delayer 16. The OFDM signal to which the CP is added is then converted into a radio frequency signal by an RF unit 18, which includes such as a digital to analog converter, an up-converter and a power amplifier, and is transmitted from antenna 19. The transmitting unit includes the RF unit 18 and the antenna 19.

Now, the cyclic delay will be explained in detail. For example, when performing the cyclic delay in the delay amount of 2 for the original signals represented as {a1, a2, 3a, 4a, 5a, 6a, 7a, 8a, 9a, 10a}, the signal sequence will become {9a, 10a, a1, a2, 3a, 4a, 5a, 6a, 7a, 8a}. When performing a cyclic delay in the delay amount of 5 for the same original signals, the signal sequence will become {6a, 7a, 8a, 9a, 10a, a1, a2, 3a, 4a, 5a}. As is obvious from these examples, there is no essential significance in performing a cyclic delay in a delay amount exceeding the length of the original signals. For example, when performing a cyclic delay in the delay amount of 12 for the above original signals, the signal sequence will become {9a, 10a, a1, a2, 3a, 4a, 5a, 6a, 7a, 8a}, which is the same as in the case of applying the cyclic delay in the delay amount of 2. Generally, in the case where the delay amount equals the odds obtained by dividing the delay amount by the length of the original signals, a same wave pattern is obtained by cyclic delay.

As mentioned above, the process of performing the cyclic delay on the time axis is mathematically equivalent to the process of performing the phase rotation on the frequency axis. To perform cyclic delay on the OFDM signal is mathematically equivalent to performing phase rotation with respect to each subcarrier on the frequency axis. More specifically, a process of subjecting the OFDM signal to a cyclic delay of X(0≦X<1) times the OFDM symbol is equivalent to a process of performing phase rotation of −360*X*k degrees on the kth subcarrier in the case where there are K pieces of subcarriers.

When such phase rotation occurs, generally, the relative phase relations among the subcarriers change. However, according to the present embodiment, it is possible to prevent the relative phase relations among the subcarriers to which the first modulation symbols are allocated from changing due to cyclic delay. The principles are explained as follows.

In the case of applying cyclic delay in the delay amount corresponding to d/N times the symbol length as in the present embodiment, a phase rotation amount p[k] in the kth subcarrier can be described as follows.

p[k]=360/N*d*k (1)

Accordingly, the difference between the phase rotation amounts given to each of any two first subcarriers arranged in N subcarriers cycles (i.e., the difference between the phase rotation amount p[k1] and phase rotation amount p[k2], when k1−k2=N) can be described as follows.

$$\begin{matrix}p [ k 1 ] - p [ k 2 ] = 360 / N * d * k 1 - 360 / N * d * k 2 \\ = 360 / N * d * ( k 1 - k 2 ) \\ = 360 * d\end{matrix} \qquad ( 2 )$$

As d is an integer, 360*d becomes equivalent to 0. In other words, as the phase difference between the any two first subcarriers arranged in the N subcarriers cycles becomes 0 degrees, it is understood that the relative phase relation will not change by the cyclic delay.

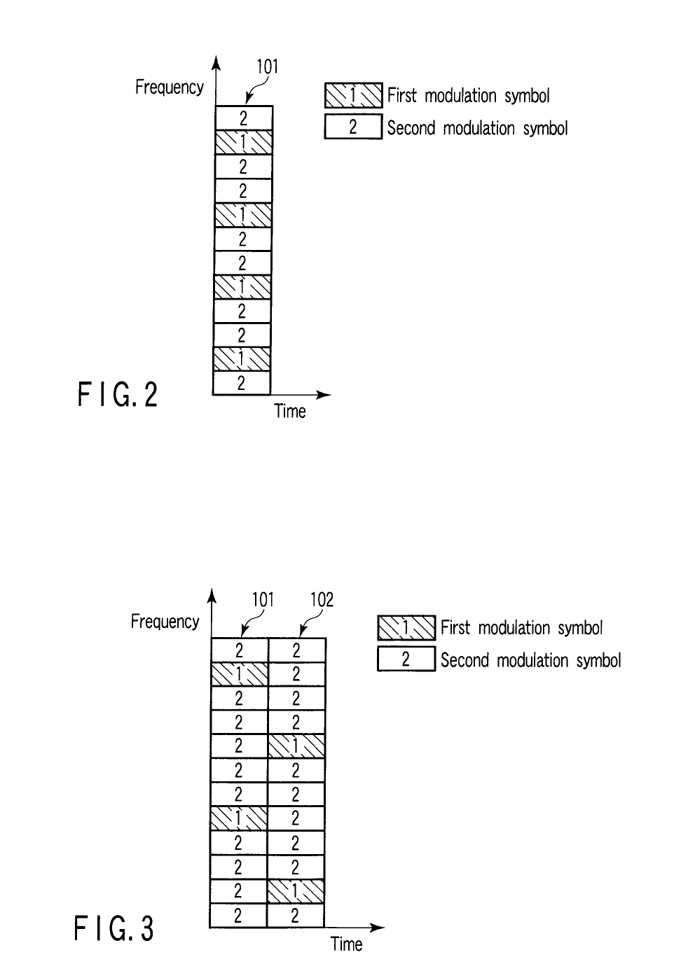

By using FIGS. 2 to 7, the following explains on how N is decided in the present embodiment. FIGS. 2 to 7 show examples of allocating the first modulation symbol and the second modulation symbol to the subcarriers on the OFDM symbol. Further, in the examples of FIGS. 2 to 7, there are 12 pieces of subcarriers included in one OFDM symbol. However, generally, there are more subcarriers included in one OFDM symbol.

FIG. 2 shows an example of the first modulation symbol and the second modulation symbol being arranging on the subcarriers of one OFDM symbol 101. In this case, the cycle of the first modulation symbol on one OFDM symbol 101 is described as N (N=3 in FIG. 2) subcarriers.

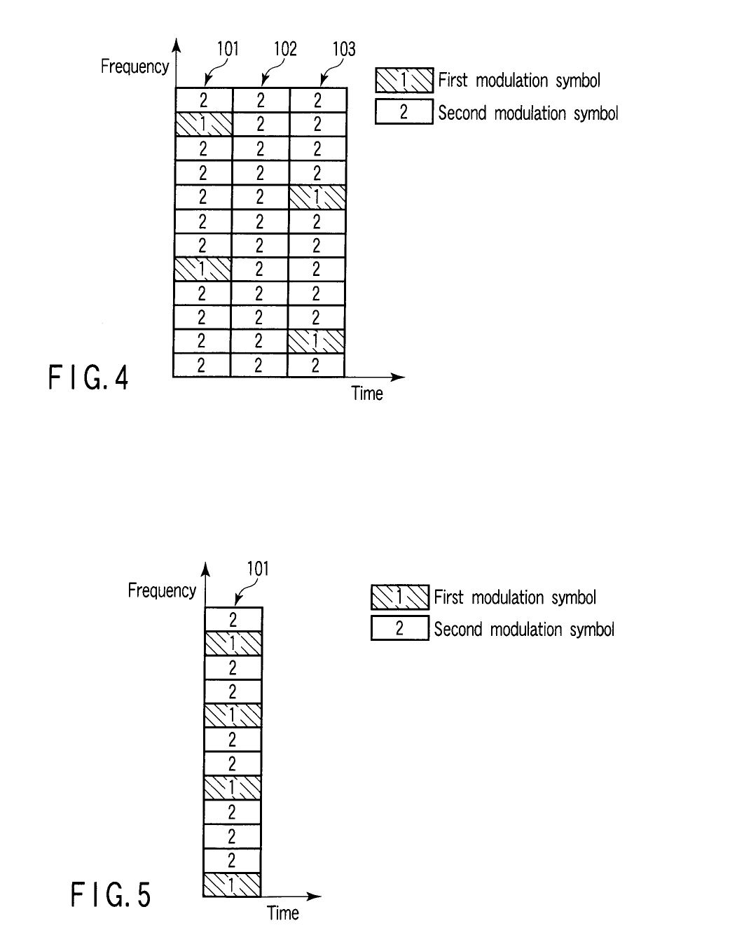

In FIGS. 3 and 4, in the case where the first modulation symbol is arranged over a plurality of OFDM symbols, the plurality of OFDM symbols are regarded as one OFDM symbol group, and the cycle of the first modulation symbol is described as N subcarriers when observing the OFDM symbol group in the direction of the frequency axis.

FIG. 3 is an example of the case in which the first modulation symbol is arranged over two OFDM symbols 101 and 102. In the example of FIG. 3, the cycle N of the first modulation symbol on the OFDM symbol group including the OFDM symbols 101 and 102 is three subcarriers cycles. Here, the cycle of the first modulation symbol on one OFDM symbol 101 or 102 is 2* N=6 subcarriers cycles.

FIG. 4 is an example of the case in which the first modulation symbol is arranged over three OFDM symbols 101, 102 and 103. Also, in the example of FIG. 4, the cycle N of the first modulation symbol on the OFDM symbol group including the OFDM symbols 101, 102 and 103 is three subcarriers cycles. In this case, the cycle of the first modulation symbol on one OFDM symbol 101 or 103 is 2*N=6 subcarriers cycles.

As shown in FIGS. 5, 6 and 7, there is no need for all first modulation symbols to be arranged in a certain subcarriers cycles. In other words, the first modulation symbol may be arranged in a plurality of different subcarriers cycles when observed in the OFDM symbol-direction (the time axis-direction). In such case, any one of the plurality of cycles of the first modulation symbols may be described as N.

For instance, in the example of FIG. 5, as there are 3 subcarriers cycles and 4 subcarriers cycles existing as subcarriers cycles of the first modulation symbols on the OFDM symbol 101, it is described as N=3 or N=4. In this case, it is preferred that a most existing cycle be selected. This is because the phase relations will not be maintained among the first modulation symbols arranged in the unselected cycles.

In the example of FIG. 5, there are more 3 subcarriers cycles. Therefore, the cycle is preferred to be described as N=3.

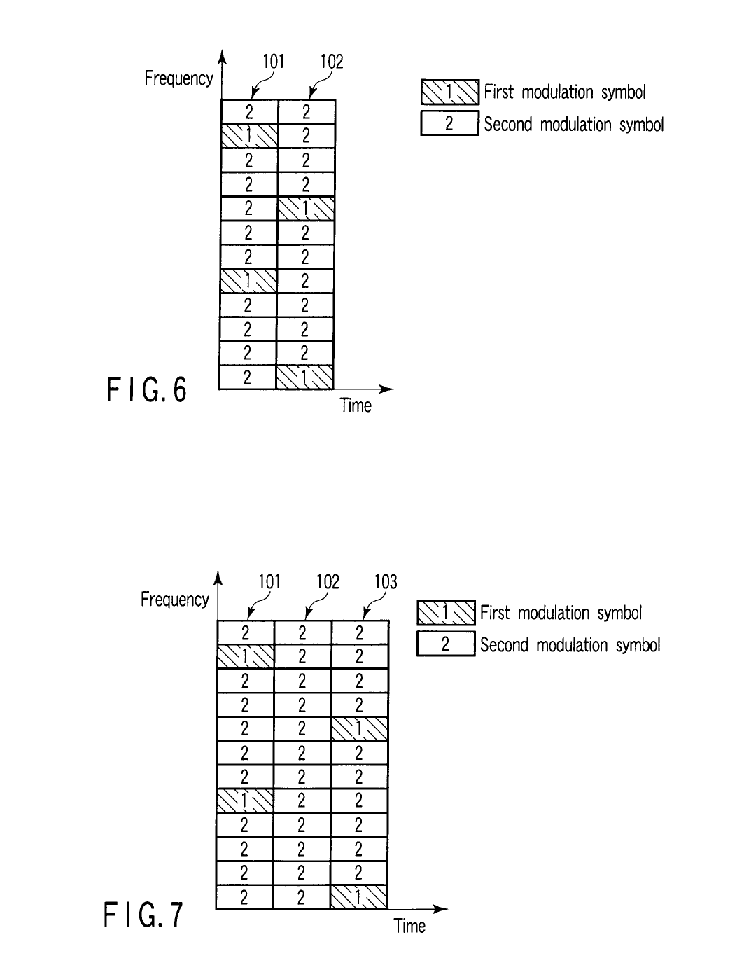

FIG. 6 is an example in the case where the first modulation symbol is arranged over the two OFDM symbols 101 and 102 likewise in FIG. 3. In the example of FIG. 3, 3 subcarriers cycles and 4 subcarriers cycles exist for the subcarriers cycles of the first modulation symbol on the OFDM symbol group including the OFDM symbols 101 and 102. Therefore the cycle is described as N=3 or N=4.

FIG. 7 is an example in the case where the first modulation symbol is arranged over0 three OFDM symbols 101 to 103 likewise in FIG. 4. Also in the example of FIG. 4, 3 subcarriers cycles and 4 subcarriers cycles exist for the subcarriers of first modulation symbol on the OFDM symbol group including the OFDM symbols 101 and 103. Therefore, the cycle can be described as N=3 or N=4.

The information of N as determined above is supplied to the cyclic delayer 16 by the subcarrier allocation unit 14.

The process carried out in the cyclic delayer 16 will be explained in detail as follows. In the following explanation, the number of samples (symbol length) of the OFDM symbol will be described as L. The symbol length L generally becomes the same value as the FFT size in the OFDM modulation. However, when a process such as up sampling or down sampling is applied after OFDM modulation, in some cases, the symbol length L may become a value other than the FFT size. For example, in the case of where a double up sampling is applied after OFDM modulation, L becomes double the size of the FFT size.

According to the first embodiment, when the symbol length of the OFDM symbol is described as L, the delay amount used in the cyclic delay is described as L*d/N. All variables of L, d and N are integers. However, depending on the value of variables, in some cases, the calculation result of L*d/N may not become integral values. In such case, the integral value which is close to the real number value (non-integral value) obtained by the calculation result should be chosen as the delay amount. In the case where the calculation result of L*d/N is an integral value, such obtained integral value should be the delay amount.

In the case where the calculation result of L*d/N is a non-integral value, a rounding operation, such as a round-off, round-down or round-up, should be applied to the non-integral value to obtain an integer. In this manner, in the case where L*d/N is a non-integral value, the difference of the relative phase rotation among the first modulation symbols can be minimized by setting the integral value which is obtained by the rounding operation of the non-integral value as the delay amount of the cyclic delay. For example, in the case where L=1024 and yet N=3, d takes the value of 0, 1 and 2, and the calculation result of L*d/n will be as follows.

1024*0/3=0 (3-1)

1024*1/3=341.3333 (3-2)

1024*2/3=682.6666 (3-3)

When rounding off the number of decimals and choosing an integer nearest to the calculation result, the delay amount corresponding to d=0, 1, 2 becomes 0, 341 and 683. In the case of truncating the number of decimals, the delay amount corresponding to d=0, 1, 2 becomes 0, 341, 682. In the case of using round-up, the delay amount corresponding to d=0, 1, 2 becomes 0, 342, 683. Here, the difference of the phase rotation amount among the subcarriers of the N subcarriers cycles, i.e., the difference of the phase rotation amount p[k1] and p[k2] when k1−k2=3, becomes;

$$\begin{matrix}p [ k 1 ] - p [ k 2 ] = 360 * ( 341 / 1024 ) * k 1 - 360 * ( 341 / 1024 ) * k 2 \\ = 360 * ( 341 / 1024 ) * 3 \\ = 359.684 …\end{matrix} \qquad ( 4 )$$

which is a value sufficiently close to 360 degrees.

As described above, according to the present embodiment, the relative phase relations among the first subcarriers to which the first modulation symbols are allocated will not change under the influence of cyclic delay. Accordingly, the character that originally consists in the first modulation symbol is maintained. For instance, in the case where the code multiplier 13 multiplies the first modulation symbol by a code possessing orthogonality or pseudo orthogonality, the orthogonality or pseudo orthogonality among the first modulation symbols can be maintained. Here, “orthogonal” means that the correlation value becomes 0, and “pseudo orthogonal” means that the absolute value of the correlation value becomes a smaller value than an auto-correlation value.

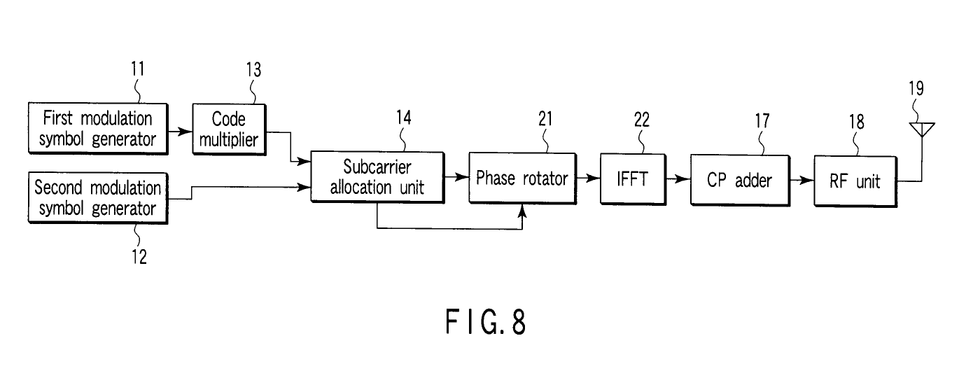

A modified example of the first embodiment will be explained in reference to FIG. 8. The wireless transmitter of FIG. 8 is different from the wireless transmitter shown in FIG. 1, in that a phase rotator 21 is arranged after the subcarrier allocation unit 14, and that an IFFT unit 22 is arranged after the phase rotator 21.

The process of performing the cyclic delay on the OFDM signal in the delay amount of X(0≦X<1) times the OFDM symbol is equivalent to the process of performing a phase rotation of −360*X*k with respect to the kth subcarrier. From this perspective, in the modified example of FIG. 8, the process of performing cyclic delay on the time axis is replaced by a process equivalent to this, which is performed on the frequency axis.

In other words, in the example of FIG. 8, the first modulation symbols allocated to the first subcarriers and the second modulation symbols allocated to the second subcarriers by the subcarrier allocation unit 14 in the same manner as in FIG. 1 are input to the phase rotator 21. In the phase rotator 21, a phase rotation is applied on the first subcarriers to which the first modulation symbols are allocated and the second subcarriers to which the second modulation symbols are allocated. The phase rotation amount in the phase rotator 21 is set to −360*d/N*k degrees (d is an integer from 0 to N−1) in accordance with the information regarding subcarrier allocation (particularly, the information on cycle N of the first subcarriers to which the first modulation symbols are allocated) given from the subcarrier allocation unit 14.

The first modulation symbols allocated to the first subcarriers and the second modulation symbols allocated to the second subcarriers which have undergone the phase rotation by the phase rotator 21 are converted into signals of the time domain from the signals of the frequency domain by the IFFT unit 22, thereby generating the OFDM signals. These OFDM signals include at least one OFDM symbol which corresponds to the first modulation symbol and the second modulation symbol.

The CP adder 17 adds CP to the OFDM signal output from the IFFT unit 22. The OFDM signal to which the CP is added is transmitted from the antenna 19 via the RF unit 18.

In this manner, the wireless transmitter in FIG. 8 is capable of generating and transmitting the OFDM signals which are equivalent to those in the wireless transmitter in FIG. 1. By this configuration, a cyclic delay can be performed on some subcarriers.

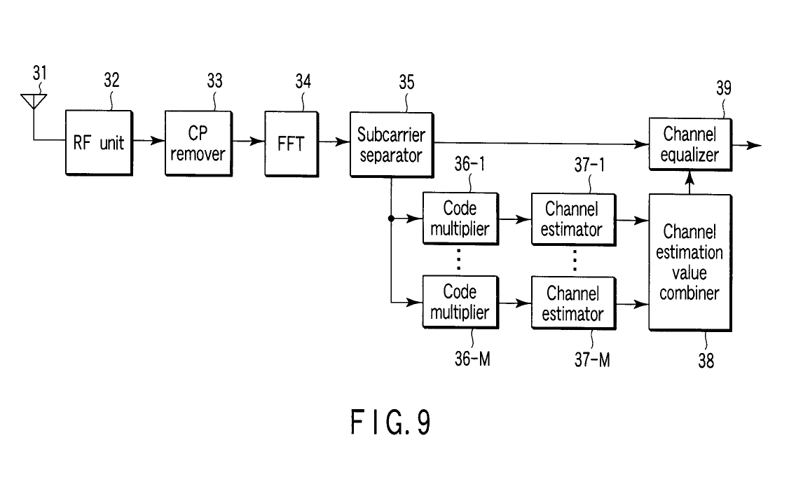

The operations of the wireless transmitters described in FIGS. 1 and 8 and a receiver described in FIG. 9 will be explained in the case where the first modulation symbols and the second modulation symbols are the same among M (M is two or more) transmitters. When the first modulation symbol is a known signal, this means that the first modulation symbol is generated by modulating a bit string known between the transmitter and receiver, or that the first modulation symbol prepared in advance is known between the transmitter and receiver.

The code by which the first modulation symbol is multiplied by the code multiplier 13 is selected as follows. In the code multiplier 13, M codes which are mutually orthogonalized or pseudo orthogonalized are prepared. Meanwhile, since d, which is a parameter to determine the delay amount, is able to take N values from 0 to N−1, N pieces of d correspond with M codes one-on-one. For example, in the case where M=3 (three transmitters) and N=3 (the cycle of the first modulation symbol is 3), the correspondence is determined as follows.

d=0 for a first code

d=1 for a second code

d=2 for a third code

A different code is set among each transmitter, and d is determined on the basis of the correspondence mentioned above. That is to say that the first code is set for the first transmitter, the second code is set for the second transmitter and the third code is set for the third transmitter, and d of the first transmitter is determined as 0, d of the second transmitter is determined as 1 and d of the third transmitter is determined as 2. The correspondence information between the code and d is shared between the transmitter and the receiver.

In the case where N is smaller than M, a certain value of d may correspond to a plurality of codes. For example, in the case where M=3 and N=2, the correspondence is determined as follows.

d=0 for the first code

d=0 for the second code

d=1 for the third code

In this case, the first code is set for the first transmitter, the second code is set for the second transmitter and the third code is set for the third transmitter, and d of the first transmitter is determined as 0, d of the second transmitter is determined as 0 and d of the third transmitter is determined as 1.

The wireless receiver will be explained using FIG. 9. In reference to FIG. 9, the OFDM signal transmitted from the wireless transmitter in FIG. 1 is received by an antenna 31. The received OFDM signal output from the antenna 31 is converted into baseband digital signal by a RF unit 32 which includes, for example, a low noise amplifier, down converter and analogue to digital converter. The baseband digital signal is input to a cyclic prefix (CP) remover 33 to have the CP removed.

The baseband digital signal which had the CP removed is converted from the signal of the time domain into a signal of the frequency domain, i.e., to a signal of each subcarrier, by the fast Fourier transform unit 34. The signal of each subcarrier is separated into the first modulation symbol and the second modulation symbol by a subcarrier separator 35.

The first modulation symbol separated by the subcarrier separator 35 is multiplied by a code by code multipliers 36-1 to 36-M. The codes set in each of the code multipliers 36-1 to 36-M are the same codes as those set in each of the transmitters. In the case where M=3 (there are three transmitters) as mentioned above, the first code, the second code and the third code are respectively prepared for each of the code multipliers 36-1, 36-2 and 36-3. Accordingly, the first modulation symbols which were multiplied by M codes in the code multiplier 13 in FIG. 1 are output from the code multipliers 36-1 to 36-M. Meanwhile, the second modulation symbols separated by the subcarrier separator 35 are input to a channel equalizer 39.

In channel estimators 37-1 to 37-M, an individual channel response corresponding to each code is estimated by using the first modulation symbols output from the code multipliers 36-1 to 36-M. The thus obtained individual channel estimation values are combined in a channel estimation value combiner 38, and a combined channel estimation value is obtained. In the channel equalizer 39, the second modulation symbols from the subcarrier separator 35 are subject to channel equalization, i.e., the process of compensating a channel response, by using the combined channel estimation value.

In the following, the process of outputting the first modulation symbols from the code multipliers 36-1 to 36-M, wherein the first modulation symbols have been multiplied by M codes, will be explained in detail. As mentioned above, M codes are mutually in orthogonal or pseudo orthogonal relations. Accordingly, by multiplying the first modulation symbol by a certain code, the signal power of the first modulation signals multiplied by other codes is weakened, and a desired signal can be output. In other words, by multiplying the first modulation symbols by M codes, the signals multiplied by each code can be extracted. M signals obtained in this manner are respectively applied the cyclic delay by the corresponding d as mentioned above.

The process of estimating individual channel responses in the channel estimators 37-1 to 37-M will be explained. The first modulation symbols multiplied by a code and extracted are the signals allocated to the first subcarriers in the N subcarriers cycles. Therefore, in the channel estimators 37-1 to 37-M, the signals allocated to the N−1 subcarrier among the first subcarriers are obtained through interpolation by using, for example, a filter. Further, the channel estimators 37-1 to 37-M output the individual channel estimation value to the channel estimation value combiner 38 by performing phase rotation on the signals obtained by interpolation based on the corresponding d. In this manner, the OFDM signals are transmitted from a plurality of wireless transmitters possessing the configuration shown in FIG. 1 or 8 by a different d, and is received by the wireless receiver in FIG. 9.

As explained above, according to the first embodiment, it is possible to eliminate or minimize the changes in the phase difference among the subcarriers which is caused by cyclic delay when applying the cyclic delay diversity on the OFDM communication system.

### Second Embodiment

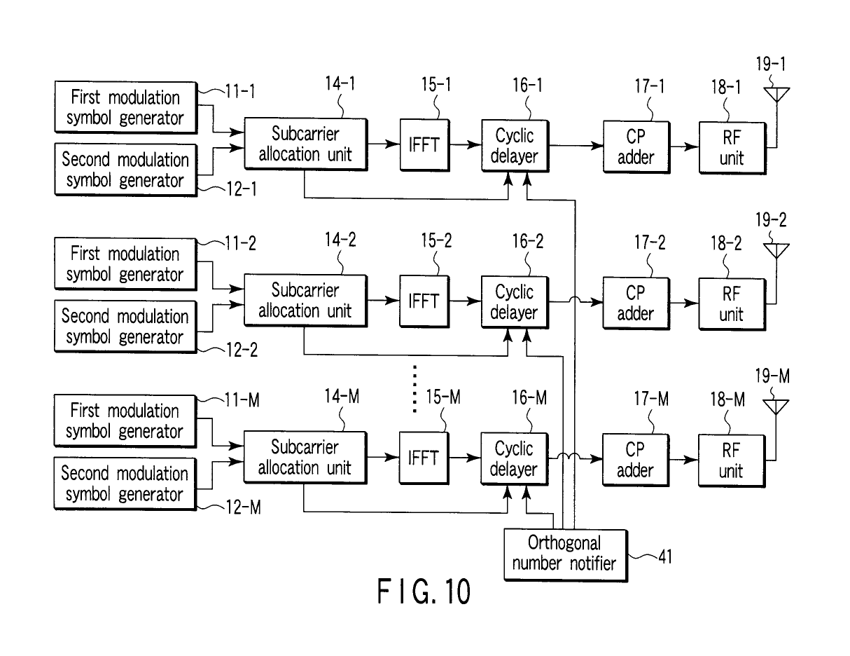

A second embodiment will be explained in reference to FIG. 10. The plurality of wireless transmitters shown in the second embodiment possesses first modulation symbol generators 11-1, 11-2, . . . , 11-M, second modulation symbol generators 12-1, 12-2, . . . , 12-M, subcarrier allocation units 14-1, 14-2, . . . , 14-M, IFFT units 15-1, 15-2, . . . , 15-M, cyclic delayers 16-1, 16-2, . . . , 16-M, CP adders 17-1, 17-2, . . . , 17-M, RF units 18-1, 18-2, . . . , 18-M, antennas 19-1, 19-2, . . . , 19-M, and further, an orthogonal number notifier 41. The first modulation symbols and the second modulation symbols are equivalent among the plurality of wireless transmitters.

In the case of focusing on one wireless transmitter, it differs from FIG. 1 in that it has no code multiplier 13 and the operation of the cyclic delayer 16 is different. Each delay amount of the cyclic delayers 16-1, 16-2, . . . , 16-M is set in accordance with the information of the orthogonal numbers M (here, the number of wireless transmitters) given from the orthogonal number notifier 41 so as to become a value which corresponds to d/N/M times the length of the OFDM symbol (M is an integer equal to two or more, and d is an integer from 0 to M−1). In this case, the first modulation symbols undergone cyclic delay by different delaying time using different ds become mutually orthogonal. Accordingly, orthogonality can be created without particularly multiplying the first modulation symbol by the orthogonal code. The following explains the principle of obtaining orthogonality without using the orthogonal code.

As mentioned above, in the case where the OFDM signal is subject to cyclic delay in the delay amount corresponding to d/N/M times the symbol length, the difference of the phase rotation amount among the M first modulation symbols allocated to each N subcarrier, in other words, the difference of the phase rotation amount p[k1], . . . , p[kM], when set as

k1−k2=N

k1−k3=2*N

. . .

k1−kM=(M−1)*N (5)

will be as follows.

$$\begin{matrix}p [ k 1 ] - p [ k 1 ] = 360 / N / M * d * ( k 1 - k 2 ) \\ = 360 * 0 / M * d\end{matrix} \\ \begin{matrix}p [ k 1 ] - p [ k 2 ] = 360 / N / M * d * ( k 1 - k 2 ) \\ = 360 * 1 / M * d\end{matrix} \\ … \\ \begin{matrix}p [ k 1 ] - p [ k M ] = 360 / N / M * d * ( k 1 - k M ) \\ = 360 * ( M - 1 ) / M * d\end{matrix} \qquad ( 6 )$$

In other words, it is understood that the process to perform cyclic delay on the M first modulation symbols is equivalent to the process of multiplying the first modulation symbols by the following codes.

(e^{2π×(0/M)×d},e^{2π×(0/M)×d}, . . . ,e^{2π×((M-1)/M×d)} (7)

Here, the two codes defined by d1 and d2 which possess different values from 0 to M−1 are understood as being mutually orthogonal based on the relations of the following equation.

$${\sum }_{m = 0}^{M - 1} {e}^{2 π \times ( m / M ) \times {d}_{1}} \times {e}^{- 2 π \times ( m / M ) \times {d}_{2}} = {\sum }_{m = 0}^{M - 1} {e}^{2 π \times ( m / M ) \times ( {d}_{1} - {d}_{2} )} = 0 \qquad ( 8 )$$

For the signals transmitted in accordance with a certain integer M in this matter, in the case where different ds are set, the first modulation symbols become mutually orthogonal. Accordingly, by setting the number of wireless transmitters desired to be orthogonalized as M, it is possible to give orthogonality to the first modulation symbols among each of the wireless transmitters.

The way to determine N in the second embodiment is the same as that in the first embodiment. Therefore, the explanations thereof will be omitted.

According to the second embodiment, when the symbol length of the OFDM symbol is described as L, the delay amount used for cyclic delay is represented as L*d/N/M. The variables L, d, N and M are all integers. However, depending on the value of these variables, in some cases, the calculation result of L*d/N/M may not become integral values. In such case, an integral value which is close to the real value (non-integral value) obtained by the calculation result is chosen, and is set as the delay amount. In the case where the calculation result of L*d/N/M is an integral value, obviously, such integral value becomes the delay amount.

In the case where the calculation result of L*d/N/M is a non-integral value, a rounding operation, such as a round-off, round-down or round-up, should be applied to the non-integral value to obtain an integer. In this manner, in the case where L*d/N/M is a non-integral value, the difference of the relative phase rotation among the first modulation symbols can be minimized by obtaining an integral value using the rounding operation and by setting such integral value as the delay amount of the cyclic delay. For example, in the case where L=1024, N=3, and yet, M=3, d takes the value of 0, 1 and 2, and the calculation result of L*d/N/M is as follows.

1024*0/3/3=0 (9-1)

1024*1/3/3=113.7777 (9-2)

1024*2/3/3=227.5555 (9-3)

When rounding off the decimal place to choose an integer which is nearest to the calculation result, the delay amount corresponding to d=0, 1, 2 becomes 0, 114, 228. In the case of trunicating the number of decimals, the delay amount corresponding to d=0, 1, 2 becomes 0, 114, 228. In the case of rounding up, the delay amount corresponding to d=0, 1, 2 becomes 0, 114, 228.

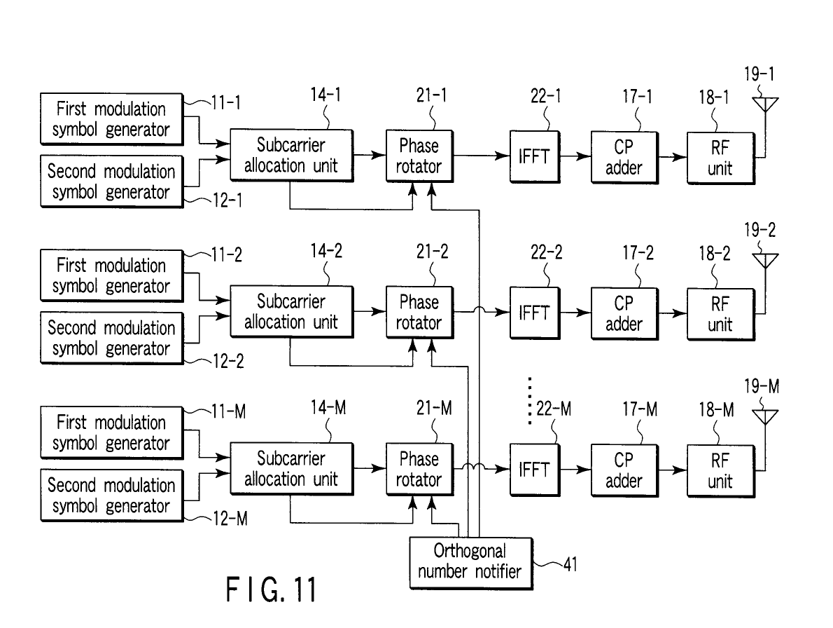

A modified example of the second embodiment will be explained in reference to FIG. 11. In comparison to the wireless transmitter shown in FIG. 10, the only difference in the wireless transmitter shown in FIG. 11 is that the phase rotators 21-1, 21-2, . . . , 21-M are respectively arranged subsequent to the subcarrier allocation units 14-1, 14-2, . . . , 14-M, and that the IFFT units 22-1, 22-2, . . . , 22-M are respectively arranged subsequent to the phase rotators 21-1, 21-2, . . . , 21-M.

As mentioned above, the process to perform cyclic delay on the OFDM signals in the delay amount of X(0≦X<1) times the OFDM symbol is equivalent to the process of performing a phase rotation of −360*X*k degrees with respect to the kth subcarrier in the case where there are K subcarriers. From this perspective, in the modified example of FIG. 11, the process of performing cyclic delay on the time axis is replaced by a process equivalent to that on the frequency axis. That is to say that, in the phase rotators 21-1, 21-2, . . . , 21-M, the phase rotation of −360*d/N/M (M is an integer of 2 or more, and d is an integer from 0 to M−1) is applied to the kth subcarrier in accordance with the orthogonal numbers M (here, the number of wireless transmitters) given from the orthogonal notifier 41.

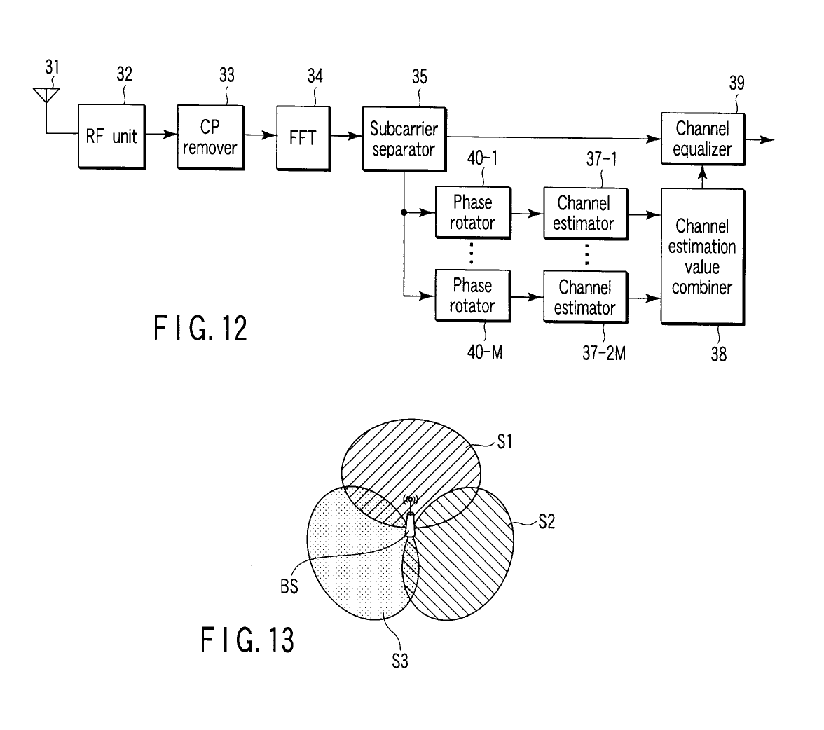

The wireless receiver will be explained using FIG. 12. In reference to FIG. 12, the OFDM signals transmitted from the wireless transmitters of FIG. 10 or 11 are received by the antenna 31. The received OFDM signals output from the antenna 31 are converted into baseband digital signals by the RF unit 32, which includes, for example, a low noise amplifier, a down converter and an analogue to digital converter. The baseband digital signals have the CPs removed by the CP remover 33.

After the CPs are removed, the baseband digital signals are converted from signals of the time domain into signals of the frequency domain, i.e., into a signal of each subcarrier, by the FFT unit 34. The signals of each of the subcarriers are divided into the first modulation symbols and the second modulation symbols by the subcarrier separator 35.

The first modulation symbols separated by the subcarrier separator 35 are input to phase rotators 40-1 to 40-M. In the phase rotation units 40-1 to 40-M, the phase differences among the adjacent modulation symbols in every M first modulation symbols are multiplied by the phase rotation of −360*d/M and are added the M pieces, thereby, the first modulation symbols transmitted by using a certain d are extracted. In the channel estimators 37-1 to 37-M, an individual channel estimation value is obtained by estimating a channel response individually for M wireless transmitters using the thus extracted first modulation symbols. The individual channel estimation value is combined by the channel estimation value combiner 38, and a combined channel estimation value is obtained. The channel equalizer 39 uses the combined channel estimation value to perform channel equalization on the second modulation symbols output from the subcarrier separator 35. In other words, the channel response is compensated.

The process carried out by the phase rotators 40-1 to 40-M to extract the first modulation symbols transmitted by using a certain d will be explained in detail as follows. As mentioned above, in the case where the ds are different, sequences which dispose M pieces of phase rotation amount provided to the first modulation symbols are mutually orthogonal. In other words, it can be regarded as multiplying the first modulation symbols by the M orthogonal codes. Accordingly, a desired signal can be respectively extracted by multiplying M codes likewise in the first embodiment. The thus obtained M signals are the signals which have undergone the cyclic delay by the corresponding d as mentioned above.

The process of estimating individual channel response in the channel estimators 37-1 to 37-M will be explained in detail. The first modulation symbols which were extracted by multiplying the code are the signals allocated to the first subcarriers of an N subcarriers cycles. Therefore, in the channel estimators 37-1 to 37-M, the signals allocated to N−1 subcarriers among the first subcarriers are obtained by interpolating using, for example, a filter. Further, the channel estimators 37-1 to 37-M output individual channel estimation values to the channel estimation value combiner 38 by performing a phase rotation on the signals obtained by the interpolation based on the corresponding d. In this manner, the wireless receiver in FIG. 12 receives the OFDM signals transmitted by a different d from the plurality of wireless transmitters possessing configurations as illustrated in FIG. 10 or 11.

### Third Embodiment

A third embodiment of the present invention will be explained using FIGS. 13, 14 and 15. FIG. 13 shows a cell/sector configuration used in a cellular system. As shown in FIG. 13, a cell formed by a base station BS comprises a plurality of sectors S1, S2 and S3. Each portion of sectors S1, S2 and S3 overlap with each other.

The following is an explanation in the case where the wireless transmitters according to the first and second embodiments are applied to a cellular system using this cell/sector configuration.

In the case of adapting the wireless transmitter according to the first embodiment to the cell/sector configuration, a different d is set for each sector. For example, in the case where N=3, d may be any of the three integers, 0, 1 or 2. Therefore, the three sectors, S1, S2 and S3 in FIG. 13 are allocated 0, 1 and 2, respectively. In the case where N exceeds the number of sectors, a part of d=0 to N−1 is allocated to each of the sectors S1, S2 and S3. In the case where N is smaller than the number of sectors, a part of d=0 to N−1 is allocated to the sectors more than once to allocate integers from 0 to N−1 to all sectors.

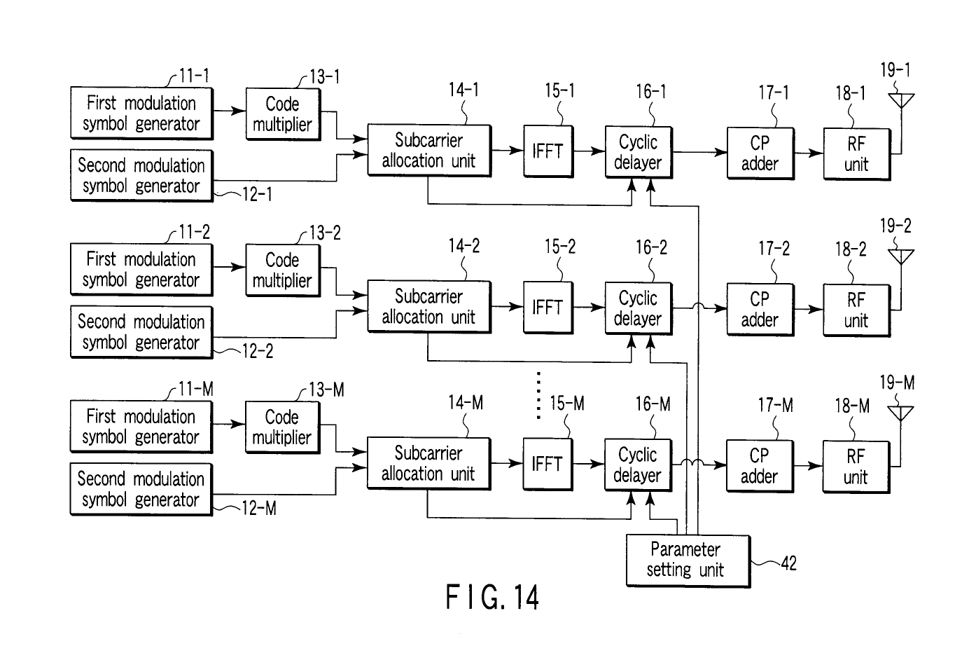

Upon setting d, for example, a parameter setting unit 42 is connected to a plurality of wireless transmitters as shown in FIG. 14. The parameter setting unit 42 sets d which is different among each sector for the cyclic delayers 16-1, 16-2, . . . , 16-M. Alternatively, a different d among each sector can be allocated to the cyclic delayers 16-1, 16-2, . . . , 16-M in advance.

By setting d in this manner, even in the case of applying cyclic delay diversity among the sectors, the original characteristics of the first modulation symbols can be maintained since the phase relations among the first modulation symbols remain unchanged. For instance, three codes being mutually orthogonal are allocated to each of the three sectors S1, S2 and S3 in FIG. 13, and the first modulation symbols are multiplied by each code by the code multipliers 13-1, 13-2, . . . , 13-M. The following is an example of the three codes being mutually orthogonal.

(1,1,1)

(e^{2π×(1/3)×1},e^{2π×(1/3)×2},e^{2π×(1/3)×3})

(e^{2π×(2/3)×1},e^{2π×(2/3)×2},e^{2π×(2/3)×3}) (10)

In the OFDM signals generated by multiplying the first modulation symbols by such codes, the first modulation symbols can be mutually orthogonal among the sectors S1, S2 and S3, as the orthogonality of the code can be maintained. This facilitates the channel estimation for each of the sectors S1, S2 and s3.

Meanwhile, in the case of adapting the wireless transmitter according to the second embodiment to the cell/sector configuration, a different d is set for each sector by regarding M as the number of sectors. For instance, in the example of FIG. 13, the number of sectors is 3. Therefore, it is described as M=3. The cyclic delay is performed by setting d=0, d=1 and d=2, respectively, for each of the three sectors S1, S2 and S3.

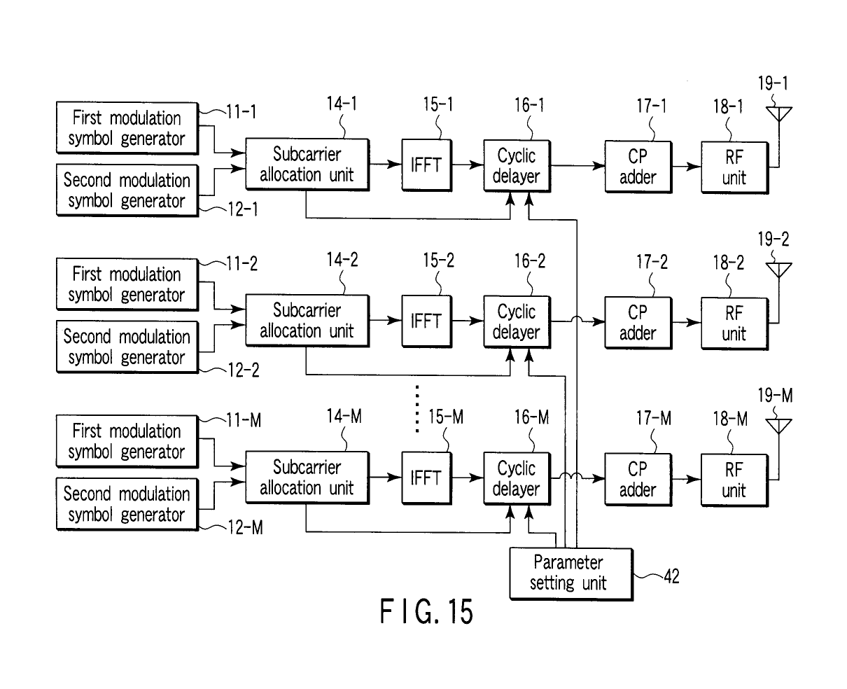

Upon setting d, for instance, as shown in FIG. 15, the parameter setting unit 42 is provided instead of the orthogonal numbers notifier 41 in the wireless transmitter shown in FIG. 10. The parameter setting unit 42 sets d which is mutually different among the sectors for the cyclic delayers 16-1, 16-2, . . . , 16-M. Alternatively, a different d among each sector may be allocated to the cyclic delayers 16-1, 16-2, . . . , 16-M in advance. By doing so, the first modulation symbols can be mutually orthogonalized without being additionally multiplied by a code.

According to this third embodiment, by using a different delay amount among the sectors in the cellular system of the cell/sector configuration, diversity gain can be effectively increased.

The receiver configuration shown in FIGS. 9 and 12 can be applied in the third embodiment as well. However, in the cell/sector configuration shown in FIG. 13, it is difficult for one certain receiver to receive signals from three transmitters all together in the same power level. Further, in the case of being near the center of a certain sector, the signal from a transmitter corresponding to the said sector may be received with stronger power than the ones from other transmitters. In the channel estimators 37-1 to 37-M, channels are estimated for each sector. However, in the case where the signal power is smaller than the others, the accuracy of its individual channel estimation value becomes lower than the others. As a result, the accuracy of the combined channel estimation value obtained by combining individual channel estimation values in the channel estimation value combiner 38 deteriorates as well. For this reason, when adapting the receivers shown in FIGS. 9 and 12 to the cell/sector configuration as shown in FIG. 13, the following process should be added to the channel estimation value combiner to improve the accuracy of the combined channel estimation value. That is, to measure each power P-1 to P-M of the individual channel estimation value output from the channel estimators 37-1 to 37-M, and in the case where the power P-m in a certain m (m=1 to M) is lower than a certain threshold value, the individual channel estimation value output from the channel estimator 37-m is not to be added to the combined calculation. The certain threshold value may be decided as an absolute value in advance, or may be calculated, for instance, on the basis of the total power of P-1 to P-M. The accuracy of the combined channel estimation value calculated in this manner can be improved since the individual channel estimation value with low accuracy will not be added.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

The present invention is effective in a wireless communication system such as in mobile communication systems using OFDM.

What is claimed is:

1. A wireless transmission method using orthogonal frequency division multiplexing (OFDM), comprising:
allocating a first modulation symbol to a plurality of first subcarriers arranged in N (N is an integer equal to 2 or more) subcarriers cycles;
performing an OFDM modulation on the first modulation symbol to generate an OFDM signal including at least one OFDM symbol corresponding to the first modulation symbol;
performing a cyclic delay on the OFDM symbol in a delay amount corresponding to either one of d/N times (d is an integer from 0 to N−1) and d/N/M times (M is an integer equal to 2 or more, d is an integer from 0 to M−1) the length of the OFDM symbol; and
transmitting the OFDM signal.

2. A wireless transmitter using an orthogonal frequency division multiplexing (OFDM), comprising:
an allocation unit configured to allocate a first modulation symbol to a plurality of first subcarriers arranged in N (N is an integer equal to 2 or more) subcarriers cycles;
a modulator to perform OFDM modulation on the first modulation symbol to generate an OFDM signal including at least one OFDM symbol corresponding to the first modulation symbol;
a cyclic delayer to perform cyclic delay on the OFDM symbol in the delay amount corresponding to either one of d/N times (d is an integer from 0 to N−1) and d/N/M times (M is an integer equal to 2 or more, d is an integer from 0 to M−1) the length of the OFDM symbol; and
a transmitting unit configured to transmit the OFDM signal.

3. The transmitter according to claim 2, wherein the delay amount is d/N times the length of the OFDM symbol, and the first modulation symbol is multiplied by a code.

4. The transmitter according to claim 3, wherein the code is one of a plurality of mutually orthogonal codes.

5. The transmitter according to claim 2, wherein d/N times or d/N/M times the length of the OFDM symbol is an integral value, and the delay amount is set as the integral value.

6. The transmitter according to claim 2, wherein d/N times or d/N/M times the length of the OFDM symbol is a non-integral value, and the delay amount is set as an integral value obtained by applying a rounding operation on the non-integral value.

7. The transmitter according to claim 6, wherein the rounding operation is at least one of round-off, round-down and round-up operations.

8. A wireless transmitter using an orthogonal frequency division multiplexing (OFDM), comprising:
an allocation unit configured to allocate a first modulation symbol to a plurality of first subcarriers arranged in N (N is an integer equal to 2 or more) subcarriers cycles;
a phase rotator to perform phase rotation on a kth subcarrier among the first subcarriers in either one of −360*d/N*k degrees (d is an integer from 0 to N−1) and −360*d/N/M*k degrees (M is an integer equal to 2 or more, d is an integer from 0 to M−1);
a modulator to perform OFDM modulation on the first modulation symbol to generate an OFDM signal including at least one OFDM symbol corresponding to the first modulation symbol;
a transmitting unit configured to transmit the OFDM signal.

9. The transmitter according to claim 8, wherein, in the case where the phase rotation amount is −360*d/N*k degrees, the first modulation symbol is multiplied by a code.

10. The transmitter according to claim 9, wherein the code is one of a plurality of mutually orthogonal codes.

11. A wireless transmitter using an orthogonal frequency division multiplexing (OFDM), comprising:
a multiplier to multiply a first modulation symbol of a known signal by a code;
an allocation unit configured to allocate a first modulation symbol to a plurality of first subcarriers arranged in N (N is an integer equal to 2 or more) subcarriers cycles, and to allocate a second modulation symbol of a data signal to a second subcarrier;
a modulator to perform OFDM modulation on the first modulation symbol allocated to the first subcarrier and the second modulation symbol allocated to the second subcarrier to generate an OFDM signal including at least one OFDM symbol corresponding to the first modulation symbol and the second modulation symbol;
a cyclic delayer to perform cyclic delay on the OFDM symbol in a delay amount corresponding to d/N times (d is an integer from 0 to N−1) the length of the OFDM symbol; and
a transmitting unit configured to transmit the OFDM signal.

12. The transmitter according to claim 11, wherein d/N times the length of the OFDM symbol is an integral value, and the delay amount is set as the integral value.

13. The transmitter according to claim 11, wherein d/N times the length of the OFDM symbol is a non-integral value, and the delay amount is set as an integral value obtained by applying a rounding operation on the non-integral value.

14. The transmitter according to claim 13, wherein the rounding operation is at least one of round-off, round-down and round-up operations.

15. A wireless transmitter using an orthogonal frequency division multiplexing (OFDM), comprising:
an allocation unit configured to allocate a first modulation symbol of a known signal to a plurality of first subcarriers arranged in N (N is an integer equal to 2 or more) subcarriers cycles, and to allocate a second modulation symbol of a data signal to a second subcarrier;
a modulator to perform OFDM modulation on the first modulation symbol allocated to the first subcarrier and the second modulation symbol allocated to the second subcarrier to generate an OFDM signal including at least one OFDM symbol corresponding to the first modulation symbol and the second modulation symbol;
a cyclic delayer to perform cyclic delay on the OFDM symbol in a delay amount corresponding to d/N/M times (M is an integer equal to 2 or more, d is an integer from 0 to N−1) the length of the OFDM symbol; and
a transmitting unit configured to transmit the OFDM signal.

16. The transmitter according to claim 15, wherein d/N/M times the length of the OFDM symbol is an integral value, and the delay amount is set as the integral value.

17. The transmitter according to claim 15, wherein d/N/M times the length of the OFDM symbol is a non-integral value, and the delay amount is set as an integral value obtained by applying a rounding operation on the non-integral value.

18. The transmitter according to claim 17, wherein the rounding operation is at least one of round-off, round-down and round-up operations.

19. A wireless receiver comprising:
a receiving unit configured to receive the OFDM signal transmitted from the wireless transmitter according to claim 11;
an IFFT unit configured to perform an inverse fast Fourier transform on the OFDM signal to separate the received OFDM signal into a signal of each subcarrier;
a separator to separate the signal of each subcarrier into the first modulation symbol and the second modulation symbol;
a multiplier to multiply the first modulation symbol by a code, to obtain a third modulation symbol;
an estimator to estimate from the third modulation symbol a channel response corresponding to the first modulation symbol, to obtain a first channel estimation value corresponding to the first modulation symbol;
a combiner to combine the first channel estimation values, to generate a second channel estimation value;
an equalizer to equalize the second modulation symbol using the second channel estimation value, to obtain a fourth modulation symbol; and
a decoder to decode the fourth modulation symbol.

20. A wireless receiver comprising:
a receiving unit configured to receive the OFDM signal transmitted from the wireless transmitter according to claim 15;
an IFFT unit configured to perform an inverse fast Fourier transform on the received OFDM signals, to separate the received OFDM signal into a signal of each subcarrier;
a separator to separate the signal of each subcarrier into the first modulation signal and the second modulation signal;
an estimator to estimate a channel response corresponding to each of the ds, by subjecting every M first modulation symbols to phase rotation so that the phase difference between the adjacent first modulation symbols becomes 360*d/M, and adding M pieces to obtain the first channel estimation value corresponding to each of the ds;
a combiner to combine the first channel estimation values, to generate a second channel estimation value;
an equalizer to equalize the second modulation symbol using the second channel estimation value, to obtain a third modulation symbol; and
a decoder to decode the third modulation symbol.

21. A wireless transmission system comprising a plurality of transmitters, each of the transmitters comprised of the transmitter according to claim 2, wherein the ds are set to have different values among each other.

22. A wireless transmission system comprising a plurality of transmitters, each of the transmitters comprised of the transmitter according to claim 8, wherein the ds are set to have different values among each other.

23. A wireless transmission system comprising a plurality of transmitters, each of the transmitters comprised of the transmitter according to claim 11, wherein the ds are set to have different values among each other.

24. A wireless transmission system comprising a plurality of transmitters, each of the transmitters comprised of the transmitter according to claim 15, wherein the ds are set to have different values among each other.

25. The wireless system according to claim 21, wherein the plurality of wireless transmitters are arranged so as to form a cell in a cellular system of a cell/sector configuration.

26. The wireless system according to claim 22, wherein the plurality of wireless transmitters are arranged so as to form a cell in a cellular system of a cell/sector configuration.

27. The wireless system according to claim 23, wherein the plurality of wireless transmitters are arranged so as to form a cell in a cellular system of a cell/sector configuration.

28. The wireless system according to claim 24, wherein the plurality of wireless transmitters are arranged so as to form a cell in a cellular system of a cell/sector configuration.
